(19) United States
(12) Patent Application Publication
(10) Pub. No.: US 2020/0058859 A1
(43) Pub. Date: Feb. 20, 2020

(54) RESISTIVE MEMORY DEVICE AND METHOD FOR FABRICATING THE SAME

(71) Applicant: MACRONIX INTERNATIONAL CO., LTD., Hsinchu (TW)

(72) Inventors: Chao-Hung WANG, Tainan City (TW); Dai-Ying LEE, Hsinchu County (TW); Kuang-Hao CHIANG, Taoyuan City (TW); Yu-Hsuan LIN, Taichung City (TW); Tsung-Ming CHEN, Zhubei City (TW)

(21) Appl. No.: 16/102,985

(22) Filed: Aug. 14, 2018

(51) Int. Cl. H01L 45/00

(52) U.S. Cl. CPC H01L 45/1253; H01L 45/1608; H01L 45/147

(57) ABSTRACT

A resistive memory device includes a first electrode, a resistance switching layer and a second electrode. The resistance switching layer is disposed on the first electrode and includes a ternary transition metal oxide. The second electrode is disposed on the resistance switching layer.

### BACKGROUND OF THE INVENTION

### Field of the Invention

The invention relates in general to a non-volatile memory (NVM) and the method for fabricating the same, and more particularly to a resistive memory and the method for fabricating the same.

### Description of the Related Art

NVMs which can continually store information even when the supply of electricity is removed from the device containing the NVM cells. Recently, the most widespread used NVMs are charge trap flash (CTF) memory devices. However, as semiconductor features shrink in size and pitch, the CTF memory devices have its physical limitation of operation. To solve the problems, resistive memory devices are thus provided.

Resistive memory devices, such as resistive random-access memory (ReRAM) devices, that apply difference of resistance resulted from different pulse voltages to respectively designate “0” or “1” states of the memory cells thereof for implementing the erase/program operation have advantages in terms of cell area, device density, power consumption, programming/erasing speed, three-dimensional integration, multi-value implementation, and the like over flash memory devices, and thus have become a most promising candidate for leading products in the future memory market.

A typical ReRAM device comprises a vertical arrangement of metal layer/memory layer/metal layer (MIM) structure which can be used to achieve high-density storage by means of a crossbar array configuration. The memory layer may be a resistance switching layer consisting of transition metal oxides (TMO), and the oxide quality of the TMO may have a huge impact on switching characteristics of the ReRAMs. Currently, binary oxides, such as titanium oxides (TiOx), have been used to composite the resistance switching layer. However, since it is hard to control the oxidation degree of the binary oxides during the process for forming the resistance switching layer, thus the switching characteristics of the ReRAMs cannot be tuned precisely.

Therefore, there is a need of providing an improved resistive memory and the method for fabricating the same to obviate the drawbacks encountered from the prior art.

### SUMMARY OF THE INVENTION

According to one embodiment of the present disclosure, a resistive memory device is provided, wherein the resistive memory device includes a first electrode, a resistance switching layer, and a second electrode. The resistance switching layer is disposed on the first electrode and includes a ternary transition metal oxide. The second electrode is disposed on the resistance switching layer.

According to another embodiment of the present disclosure, a method for fabricating a resistive memory device is provided, wherein the method includes steps as follows: Firstly, a first electrode is provided. Next, a resistance switching layer including a ternary transition metal oxide is formed on the first electrode. A second electrode is then formed on the resistance switching layer.

In accordance with the embodiments of the present disclosure, a resistive memory device and the method for fabricating the same are provided. The resistive memory device includes a stack structure constituted by a first electrode, a resistance switching layer and a second electrode stacked in sequence, wherein the resistance switching layer includes a ternary transition metal oxide. The switching characteristics of the resistive memory device can be tuned precisely to improve the performance thereof by controlling the oxidation degree of the ternary transition metal oxide (the contents of oxygen involved in the resistance switching layer) during the process for forming the resistance switching layer.

In some embodiments of the present disclosure, the forming of the resistance switching layer includes steps as follows: A TMO layer and a material layer are formed on a first electrode layer. The TMO layer and the material layer are then subjected to a thermal annealing treatment to form a metal alloy layer. Subsequently, the metal alloy layer is oxidized to form the resistance switching layer including the ternary transition metal oxide. The switching characteristics of the resistive memory device can be tuned precisely by the simple steps of controlling the oxidation degree of the metal alloy oxide for forming the resistance switching layer.

In some embodiments of the present disclosure, the resistive memory device may have multiple-resistance states, by which 10 to 1024 states can be provided within a resistance interval ranging of 10 K-Ohm to 200 K-Ohm, when a plurality of set/reset pulses are applied thereto. Such that, the resistive memory device having multiple resistance states can be used as an analog switch involved in an analog neuromorphic circuit to provide an analog behavior model (ABM) for a neural network application.

### BRIEF DESCRIPTION OF THE DRAWINGS

The above and other aspects of the disclosure will become better understood with regard to the following detailed description of the preferred but non-limiting embodiment(s). The following description is made with reference to the accompanying drawings.

FIGS. 1A to 1E are cross-sectional views illustrating the processing structures for fabricating a resistive memory device, in accordance with one embodiment of the present disclosure;

FIG. 1B′ illustrates a cross-sectional view after a patterned material layer and a first patterned TMO layer are formed in sequence on the structure as depicted in FIG. 1A in accordance with another embodiment of the present disclosure;

FIGS. 2A to 2B are cross-sectional views illustrating portions of the processing structures for fabricating a resistive memory device, in accordance with another embodiment of the present disclosure;

FIGS. 3A to 3C are cross-sectional views illustrating portions of the processing structures for fabricating a resistive memory device, in accordance with yet another embodiment of the present disclosure;

FIGS. 4A to 4C are cross-sectional views illustrating portions of the processing structures for fabricating a resistive memory device, in accordance with yet another embodiment of the present disclosure;

FIGS. 5A to 5B are cross-sectional views illustrating portions of the processing structures for fabricating a resistive memory device, in accordance with another embodiment of the present disclosure;

FIG. 6 is a diagram illustrating the cumulative distribution function (CDF) of a ReRAM cell applying the resistive memory device that is provided by the method described in FIGS. 1A to 1E under different operation conditions in accordance with one embodiment of the present disclosure; and

FIGS. 7A and 7B are diagrams respectively illustrating the CDFs of the ReRAM cell after subjected to a plurality of stepping set/reset pluses respectively in accordance with another embodiment of the present disclosure.

### DETAILED DESCRIPTION OF THE INVENTION

A resistive memory device and the method for fabricating the same are provided to tune the switching characteristics of the resistive memory device more precisely and improve the performance thereof. Several embodiments of the present disclosure are disclosed below with reference to accompanying drawings.

However, the structure and contents disclosed in the embodiments are for exemplary and explanatory purposes only, and the scope of protection of the present disclosure is not limited to the embodiments. Designations common to the accompanying drawings and embodiments are used to indicate identical or similar elements. It should be noted that the present disclosure does not illustrate all possible embodiments, and anyone skilled in the technology field of the invention will be able to make suitable modifications or changes based on the specification disclosed below to meet actual needs without breaching the spirit of the invention. The present disclosure is applicable to other implementations not disclosed in the specification. In addition, the drawings are simplified such that the content of the embodiments can be clearly described, and the shapes, sizes and scales of elements are schematically shown in the drawings for explanatory and exemplary purposes only, not for limiting the scope of protection of the present disclosure.

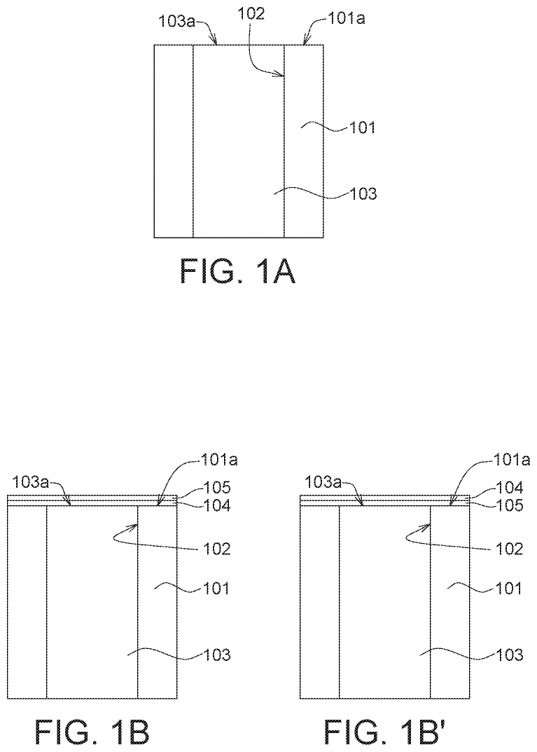

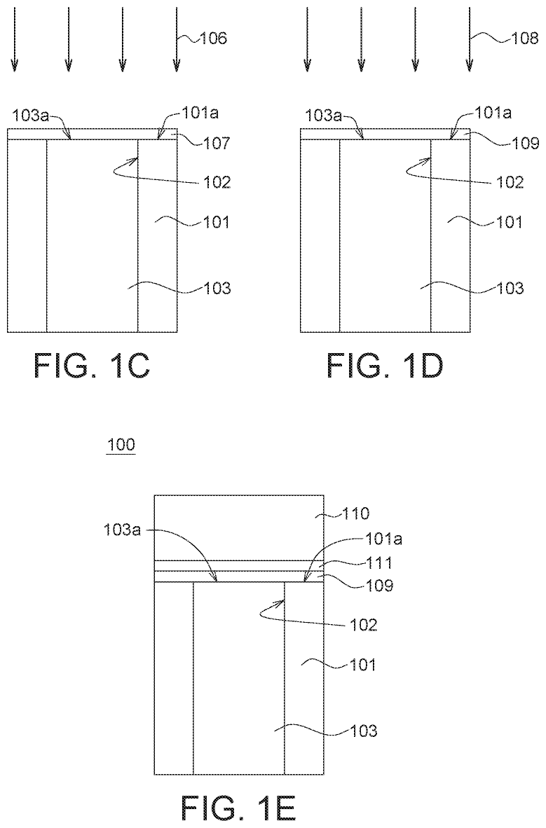

FIGS. 1A to 1E are cross-sectional views illustrating the processing structures for fabricating a resistive memory device 100, in accordance with one embodiment of the present disclosure. The method for forming the resistive memory 100 includes steps as follows: Firstly, a dielectric layer 101 is provided. In some embodiments of the present disclosure, the dielectric layer 101 may be an inter-layer dielectric layer (ILD) made of silicon oxide (SiOx).

Next, at least one opening 102 is formed in the dielectric layer 101 by a patterning process (not shown) performed on the top surface 101a of the dielectric layer 101. The opening 102 is then fulfilled by a conductive material. A planarization process, such as a chemical-mechanical planarization (CMP) using the top surface 101a of the Si-containing substrate 101 as a stop layer (not shown), is then performed to remove a portion of the conductive material to form a first electrode 103 in the opening 102, wherein the first electrode 103 has a top surface 103a substantially conplanar to the top surface 101a of the dielectric layer 101 (see FIG. 1A).

In some embodiments of the present disclosure, the opening 102 can be a through-hole passing through the dielectric layer 101. The first electrode 103 is made of a material selected from a group consisting of tungsten (W), titanium nitride (TiN), copper (Cu), aluminum (Al), gold (Au), silver (Ag), platinum (Pt), titanium (Ti) and the arbitrary combinations thereof. In the present embodiment, the first electrode 103 can be a via plug made of W and penetrating through the ILD (the dielectric layer 101), wherein the first electrode 103 has a thickness substantially ranging from 100 nm to 500 nm.

A first patterned TMO layer 104 and a patterned material layer 105 made of a material other than that of the first patterned TMO layer 104 are then formed on the top surface 103a of the first electrode 103 by a depositing process, such as a low-pressure chemical vapor deposition (LPCVD) (see FIG. 1B). In some embodiments of the present disclosure, the first patterned TMO layer 104 may be made of a material selected from a group consisting of hafnium (Hf), W, Al, Cu, nickel (Ni), germanium (Ge), Ti and the arbitrary combinations thereof; and the patterned material layer 105 may be made of a material selected from a group consisting of silicon (Si), Hf, W, Al, Cu, Ni, Ge, Ti, zirconium (Zr), niobium (Nb), tantalum (Ta) and the arbitrary combinations thereof. Both of the first patterned TMO layer 104 and the patterned material layer 105 have a thickness substantially less than 50 angstrom (Å), and the thickness of the first patterned TMO layer 104 may be greater than that of the patterned material layer 105.

In the present embodiment, the first patterned TMO layer 104 can be a Ti layer disposed on and directly contacting to the first electrode 103, and the patterned material layer 105 can be a Si layer aligning to, disposed on and directly contacting to the Ti layer (the first patterned TMO layer 104). The Ti layer (the first patterned TMO layer 104) may have a thickness substantially ranging from 1 Å to 50 Å; and the Si layer (the patterned material layer 105) may have a thickness substantially ranging from 1 Å to 50 Å. The ratio of the thickness of the Ti layer (the first patterned TMO layer 104) to the thickness of the Si layer (the patterned material layer 105) preferably can be about 3/2.

Of note that, although the facts, as shown in FIG. 1B, that the patterned material layer 105 is stacked over the first patterned TMO layer 104 may indicate that the first patterned TMO layer 104 is formed prior to the forming of the patterned material layer 105, but the step sequence for forming the first patterned TMO layer 104 and the patterned material layer 105 may not limited to this regard. FIG. 1B′ illustrates a cross-sectional view after a patterned material layer 105 and a first patterned TMO layer 104 are formed in sequence on the structure as depicted in FIG. 1A in accordance with another embodiment of the present disclosure. In the present embodiment, the first patterned TMO layer 104 which is formed prior to the forming of the patterned material layer 105 is stacked over the patterned material layer 105.

Thereinafter, the first patterned TMO layer 104 and the patterned material layer 105 are subjected to a thermal annealing treatment 106, so as to form a metal alloy layer 107 (see FIG. 1C). In some embodiments of the present disclosure, the thermal annealing treatment 106 may be performed in a temperature ranging from 50° C. to 850° C. for a time longer than 40 seconds. In the present embodiment, the thermal annealing treatment 106 applied to transform the Ti layer (the first patterned TMO layer 104) and the Si layer (the patterned material layer 105) into a silicide layer (the metal alloy layer 107) preferably may include a step for heating the Ti layer (the first patterned TMO layer 104) and the Si layer (the patterned material layer 105) to a temperature about 650° C. for 50 seconds.

However, the material made of the metal alloy layer 107 may not be limited to this regard. For example, in some other embodiments, the metal alloy layer 107 alternatively may be a Hf—Si alloy layer, an Al—Si alloy layer, a W—Si alloy layer, a Cu—Si alloy layer, a Ni—Si alloy layer, a Ge—Si alloy layer, a Ti—Ge alloy layer, an Al—Ge alloy layer, a W—Ge alloy layer, a Cu—Ge alloy layer, a Ni—Ge alloy layer, a W—Ti alloy layer, a Cu—Al alloy layer, an Al—Ti alloy layer or a Hf—Ti alloy layer.

The metal alloy layer 107 is then subjected to an oxidization process 108 to form a resistance switching layer 109 (see FIG. 1D). In some embodiments of the present disclosure, the oxidization process 108 may be include steps of using oxygen-containing plasma to bombard the metal alloy layer 107 or steps of thermal oxidation directly performed in an oxidation furnace. In the present embodiment, the metal alloy layer 107 is preferably oxidized by an oxygen-containing plasma bombardment to form a resistance switching layer 109 made of titanium-silicon oxide (TiₓSi_{y}O_{1-x-y}), wherein 1<x/y<100. The resistance switching layer 109 has a thickness substantially ranging from 1 Å to 200 Å.

However, the material made of the resistance switching layer 109 may not be limited to this regard. For example, in some other embodiments, the resistance switching layer 109 alternatively may be made of metal-silicon oxides, such as Hf—Si oxide (HfₓSi_{y}O_{1-x-y}, wherein 1<x/y<100), Al—Si oxide (AlₓSi_{y}O_{1-x-y}, wherein 1<x/y<100), W—Si oxide (WₓSi_{y}O_{1-x-y}, wherein 1<x/y<100), Cu—Si oxide (CuₓSi_{y}O_{1-x-y}, wherein 1<x/y<100), Ni—Si oxide (NiₓSi_{y}O_{1-x-y}, wherein 1<x/y<100) or Ge—Si oxide (GeₓSi_{y}O_{1-x-y}, wherein 1<x/y<100); metal-germanium oxide, such as Ti—Ge oxide (TiₓGe_{y}O_{1-x-y}, wherein 1<x/y<100), Al—Ge oxide (AlₓGe_{y}O_{1-x-y}, wherein 1<x/y<100), W—Ge oxide (WₓGe_{y}O_{1-x-y}, wherein 1<x/y<100), Cu—Ge oxide (CuₓGe_{y}O_{1-x-y}, wherein 1<x/y<100), Ni—Ge oxide (NiₓGe_{y}O_{1-x-y}, wherein 1<x/y<100); or metal-titanium oxide, such as W—Ti oxide (WₓGe_{y}O_{1-x-y}, wherein 1<x/y<100), Cu—Al oxide (CuₓGe_{y}O_{1-x-y}, wherein 1<x/y<100), Al—Ti oxide (AlₓGe_{y}O_{1-x-y}, wherein 1<x/y<100) or Hf—Ti oxide (HfₓGe_{y}O_{1-x-y}, wherein 1<x/y<100).

Subsequently, a second electrode 110 is then formed on the resistance switching layer 109. In some embodiments of the present disclosure, the forming of the second electrode 110 includes steps as follows: A conductive layer (not shown) is firstly formed on the resistance switching layer. Then, a portion of the conductive layer can be remove by an etching process (not shown) to expose a portion of the top surface 101a of the dielectric layer, and the remaining portion of the conductive layer disposed on and aligned to the resistance switching layer 109 can serve as the second electrode 110. The material used to constitute the second electrode 110 can be identical to or different from that used to constitute the first electrode 103. In the present embodiment, the material used to constitute the second electrode 110 is identical that used to constitute the first electrode 103; and the second electrode 110 has a thickness substantially ranging from 1 Å to 10000 Å.

In some embodiments, a metal oxide layer 111 can be optionally formed on the resistance switching layer 109 prior to the forming of the second electrode 110. The metal oxide layer 111 may be made of at least one of TiOx and titanium oxynitride (TiON). The contents of the oxygen ion driven into the resistance switching layer 109 from the metal oxide layer 111 can be precisely controlled by estimating the oxygen concentration of the metal oxide layer 111 and the thermal budge of the subsequent process formed thereon, such as the process for forming the second electrode 110, thereby the oxidation degree of the ternary transition metal oxide (the contents of oxygen involved in the resistance switching layer 109) can be tuned more precisely, and thus the switching characteristics of the resistance switching layer 109 can be further improved.

After a series downstream process are carried out, the resistive memory device 100 as depicted in FIG. 1E can be implemented.

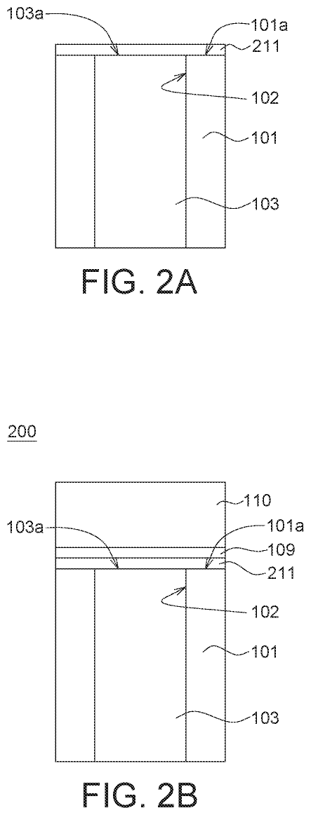

FIGS. 2A to 2B are cross-sectional views illustrating portions of the processing structures for fabricating a resistive memory device 200, in accordance with another embodiment of the present disclosure. The structure of the resistive memory device 200 is similar that of the resistive memory device 100 except that the metal oxide layer 211 is disposed between the first electrode 103 and the resistance switching layer 109.

In the present embodiment, the forming of the resistive memory device 200 includes steps as follows: Prior to the forming of the resistance switching layer 109, a metal oxide layer 211 may be formed on and aligned to the top surface 103a of the first electrode 103 (see FIG. 2A). The resistance switching layer 109 and the second electrode 110 are then formed in sequence to stack on the metal oxide layer 211, and after a series downstream process are carried out, the resistive memory device 200 as depicted in FIG. 2B can be implemented. Since the method and processes for forming the other elements of the resistive memory device 200 except the metal oxide layer 211 have been described above, thus the detailed descriptions of the same will not be redundantly described here.

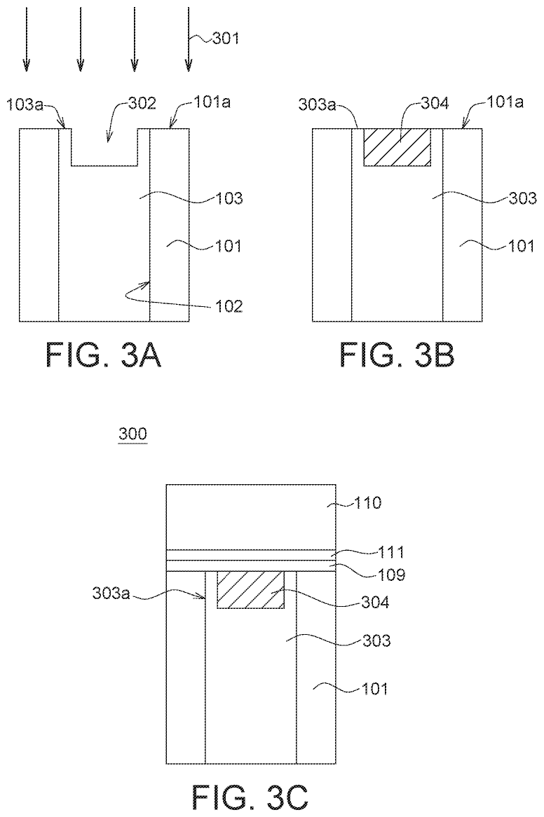

FIGS. 3A to 3C are cross-sectional views illustrating portions of the processing structures for fabricating a resistive memory device 300, in accordance with yet another embodiment of the present disclosure. The structure of the resistive memory device 300 is similar that of the resistive memory device 100 except that the first electrode 303 has a ring-shaped contacting structure 303a.

In the present embodiment, the forming of the resistive memory device 300 includes steps as follows: Prior to the forming of the resistance switching layer 109 and the metal oxide layer 111, the first electrode 103 as depicted in FIG. 1A may be subjected to an etching process 301 to remove a portion of the first electrode 103 and remain a portion of the top surface 103a of the first electrode 103, whereby a recess 302 surrounded by the remaining portion of the first electrode 103 can be formed (see FIG. 3A). The recess 302 is then filled with a dielectric material 304, and a planarization process using the remaining portion of the first electrode 103 as a stop layer is then performed to remove the portion of the dielectric material 304 disposed on the top surface 103a of the remaining portion of the first electrode 103, so as to form the first electrode 303 having a ring-shaped contacting structure 303a surrounding the remaining portion of the dielectric material 304 (see FIG. 3B).

The metal oxide layer 111, the resistance switching layer 109 and the second electrode 110 are then formed in sequence to stack on the first electrode 303, and after a series downstream process are carried out, the resistive memory device 300 as depicted in FIG. 30 can be implemented. Since the method and processes for forming the other elements of the resistive memory device 300 other than the first electrode 303 have been described above, thus the detailed descriptions of the same will not be redundantly described here.

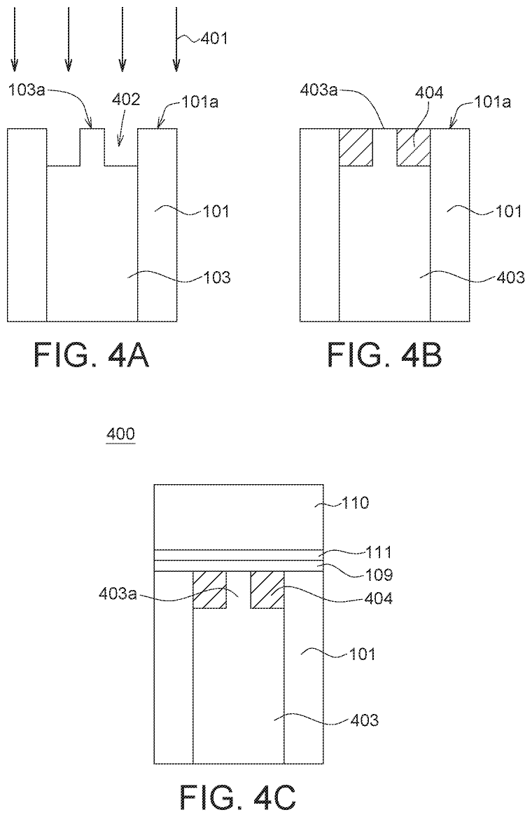

FIGS. 4A to 4C are cross-sectional views illustrating portions of the processing structures for fabricating a resistive memory device 400, in accordance with yet another embodiment of the present disclosure. The structure of the resistive memory device 400 is similar that of the resistive memory device 100 except that the first electrode 403 has a protruding portion 403a.

In the present embodiment, the forming of the resistive memory device 400 includes steps as follows: Prior to the forming of the resistance switching layer 109 and the metal oxide layer 111, the first electrode 103 as depicted in FIG. 1A may be subjected to an etching process 401 to remove a portion of the first electrode 103 and remain a portion of the top surface 103a of the first electrode 103, whereby a recess 402 surrounding the top surface 103a of the remaining portion of the first electrode 103 an be formed (see FIG. 4A). The recess 402 is then filled with a dielectric material 404, and a planarization process using the remaining portion of the first electrode 103 as a stop layer is then performed to remove the portion of the dielectric material 404 disposed on the top surface 103a of the remaining portion of the first electrode 103, so as to form the first electrode 403 having the protruding portion 403b surrounded by the remaining portion of the dielectric material 404 (see FIG. 4B).

The metal oxide layer 111, the resistance switching layer 109 and the second electrode 110 are then formed in sequence to stack on the first electrode 403, and after a series downstream process are carried out, the resistive memory device 400 as depicted in FIG. 4C can be implemented. Since the method and processes for forming the other elements of the resistive memory device 400 other than the first electrode 403 have been described above, thus the detailed descriptions of the same will not be redundantly described here.

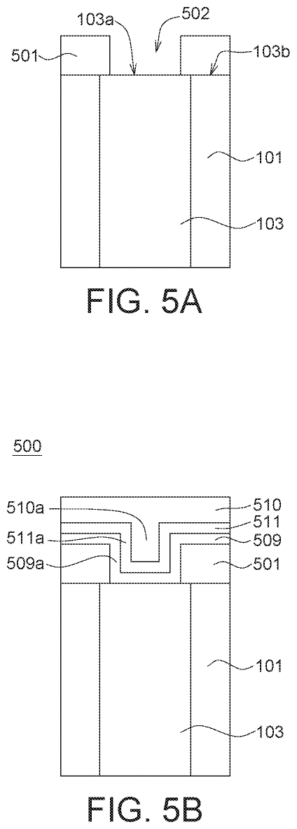

FIGS. 5A to 5B are cross-sectional views illustrating portions of the processing structures for fabricating a resistive memory device 500, in accordance with another embodiment of the present disclosure. The structure of the resistive memory device 500 is similar that of the resistive memory device 100 except that the resistance switching layer 509, the second electrode 510 and the metal oxide layer 511 of the resistive memory device 500 respectively have a protruding portions 509a, 510a and 511a.

In the present embodiment, the forming of the resistive memory device 500 includes steps as follows: Prior to the forming of the resistance switching layer 509 and the metal oxide layer 511, a patterned dielectric layer 501 having an opening 501a is formed on the top surface 101a of the dielectric layer 101 to make at least one portion of the top surface 103a of the first electrode 103 exposed from the opening 501a (see FIG. 5A).

The metal oxide layer 511, the resistance switching layer 509 and the second electrode 510 are then formed in sequence to stack on the first electrode 103 and the patterned dielectric layer 501, wherein the portions of the metal oxide layer 511, the resistance switching layer 509 and the second electrode 510 extending into the opening 501a may be shaped as protruding portions 509a, 510a and 511a respectively. After a series downstream process are carried out, the resistive memory device 500 as depicted in FIG. 5B can be implemented. Since the method and processes for forming the the metal oxide layer 511, the resistance switching layer 509 and the second electrode 510 of the resistive memory device 500 are similar to that described above, thus the detailed descriptions of the same will not be redundantly described here.

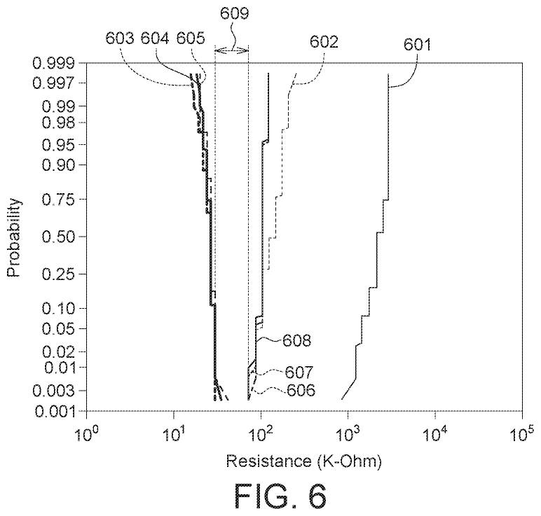

FIG. 6 is a diagram illustrating the cumulative distribution function (CDF) of a ReRAM cell applying the resistive memory device 100 that is provided by the method described in FIGS. 1A to 1E under different operation conditions in accordance with one embodiment of the present disclosure. The horizontal axis indicates the resistance of the ReRAM cell and the vertical axis indicates the cumulative number of the ReRAM cell. The curve 601 represents the CDF of the initial resistance distribution of the ReRAM cell. The curve 602 represents the CDF of the resistance, after a forming voltage is applied to the ReRAM cell. The curves 603-605 respectively represent the CDF of the resistance after a set voltage is applied to the ReRAM cell. The curves 606-608 respectively represent the CDF of the resistance after a reset voltage is applied to the ReRAM cell.

According to FIG. 6, when the ReRAM cell is set, it has a distribution area with a lower resistance (see the curves 603-605); when the ReRAM cell is reset, it has a distribution area with a higher resistance (see the curve 606-608); and there is a gap 609 separating the lower resistance distribution area from the higher resistance distribution area. The state of the ReRAM cell obtained by determining whether the resistance of the ReRAM cell is greater than a predetermined critical resistance with in the gap 609 can be utilized to indicate digital signal (i.e. “0” or “1”), thereby allowing for data storage.

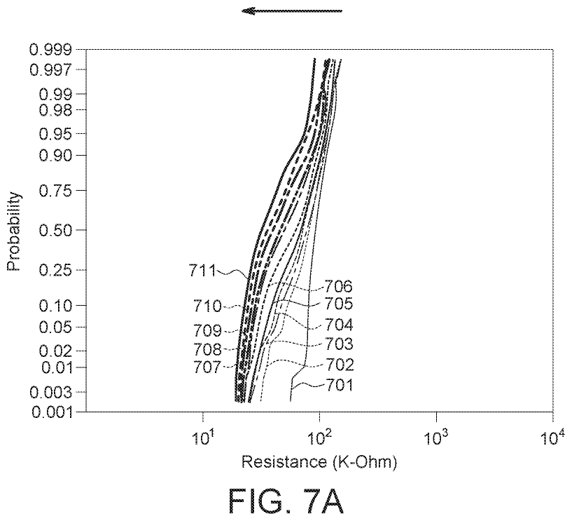

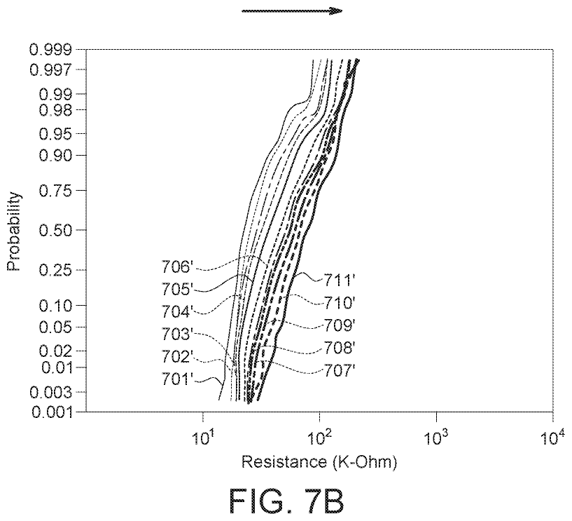

FIGS. 7A and 7B are diagrams respectively illustrating the CDFs of the ReRAM cell after subjected to a plurality of stepping set/reset pluses respectively in accordance with another embodiment of the present disclosure. The curves 701-711 respectively represent the CDF of the resistance after a plurality of set pluses are steply applied to the ReRAM cell. The curves 701′-711′ respectively represent the CDF of the resistance after a plurality of reset pluses are steply applied to the ReRAM cell.

According to FIGS. 7A and 7B, the average resistances of the ReRAM cell can be steply increased corresponding the cumulated energy of the set/reset pulses applied to the ReRAM cell, and the CDFs of the ReRAM cell may have multiple resistance states corresponding to each of the set/reset pulses (see curves 701-711/701′-711′). In some embodiments of the present disclosure, the ReRAM cell may have multiple-resistance states to provide 10 to 1024 states within a resistance interval ranging of 10 K-Ohm to 200 K-Ohm into. When the ReRAM cell may have 10 resistance states within the resistance interval, the switching accuracy of the ReRAM cell can reach to 84%; and when the number of the resistance state is greater than 100, the switching accuracy of the ReRAM cell can be increased up to greater than 96%.

The ReRAM cell having multiple resistance states can be used to serve as an analog switch involved in an analog neuromorphic circuit for a neural network application which can provided an ABM to conduct a neuromorphic computing. In some embodiments of the present disclosure, the ReRAM cell can be applied in artificial intelligence technology to configure an inference chip.

In accordance with the embodiments of the present disclosure, a resistive memory device and the method for fabricating the same are provided. The resistive memory device includes a stack structure constituted by a first electrode, a resistance switching layer and a second electrode stacked in sequence, wherein the resistance switching layer includes a ternary transition metal oxide. The switching characteristics of the resistive memory device can be tuned precisely to improve the performance thereof by controlling the oxidation degree of the ternary transition metal oxide (the contents of oxygen involved in the resistance switching layer) during the process for forming the resistance switching layer.

In some embodiments of the present disclosure, the forming of the resistance switching layer includes steps as follows: A TMO layer and a material layer are formed on a first electrode layer. The TMO layer and the material layer are then subjected to a thermal annealing treatment to form a metal alloy layer. Subsequently, the metal alloy layer is oxidized to form the resistance switching layer including the ternary transition metal oxide. The switching characteristics of the resistive memory device can be tuned precisely by the simple steps of controlling the oxidation degree of the metal alloy oxide for forming the resistance switching layer.

In some embodiments of the present disclosure, the resistive memory device may have multiple-resistance states, by which 10 to 1024 states can be provided within a resistance interval ranging of 10 K-Ohm to 200 K-Ohm, when a plurality of set/reset pulses are applied thereto. Such that, the resistive memory device having multiple resistance states can be used as an analog switch involved in an analog neuromorphic circuit to provide an ABM for a neural network application.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A resistive memory device comprising:
a first electrode;
a resistance switching layer, disposed on the first electrode and comprising a ternary transition metal oxide, wherein the ternary transition metal oxide is selected from a group consisting of Ti—Si oxide (TiₓSi_{y}O_{1-x-y}), Hf—Si oxide (HfₓSi_{y}O_{1-x-y}), Al—Si oxide (AlₓSi_{y}O_{1-x-y}), W—Si oxide (WₓSi_{y}O_{1-x-y}), Cu—Si oxide (CuₓSi_{y}O_{1-x-y}), Ni—Si oxide (NiₓSi_{y}O_{1-x-y}), Ge—Si oxide (GeₓSi_{y}O_{1-x-y}), Ti—Ge oxide (TiₓGe_{y}O_{1-x-y}), Al—Ge oxide (AlₓGe_{y}O_{1-x-y}), W—Ge oxide (WₓGe_{y}O_{1-x-y}), Cu—Ge oxide (CuₓGe_{y}O_{1-x-y}), Ni—Ge oxide (NiₓGe_{y}O_{1-x-y}), W—Ti oxide (WₓTi_{y}O_{1-x-y}), Al—Ti oxide (AlₓTi_{y}O_{1-x-y}) and arbitrary combinations thereof; and
a second electrode, disposed on the resistance switching layer.

2. (canceled)

3. The resistive memory device according to claim 1, further comprising a metal oxide layer disposed between the first electrode and the second electrode.

4. The resistive memory device according to claim 3, wherein the metal oxide layer is made of at least one of titanium oxide (TiOx) and titanium oxynitride (TiON).

5. The resistive memory device according to claim 1, wherein the resistive memory device has 10 to 1024 states within a resistance interval ranging of 10 K-Ohm to 200 K-Ohm, when a plurality of set/reset pulses are applied thereto.

6. The resistive memory device according to claim 1, wherein the resistance switching layer has a thickness substantially ranging from 1 angstrom (Å) to 200 Å.

7. A method for fabricating a resistive memory device, comprising:
providing a first electrode;
forming a resistance switching layer comprising a ternary transition metal oxide on the first electrode, wherein the ternary transition metal oxide is selected from a group consisting of Ti—Si oxide (TiₓSi_{y}O_{1-x-y}), Hf—Si oxide (HfₓSi_{y}O_{1-x-y}), Al—Si oxide (AlₓSi_{y}O_{1-x-y}), W—Si oxide (WₓSi_{y}O_{1-x-y}), Cu—Si oxide (CuₓSi_{y}O_{1-x-y}), Ni—Si oxide (NiₓSi_{y}O_{1-x-y}), Ge—Si oxide (GeₓSi_{y}O_{1-x-y}), Ti—Ge oxide (TiₓGe_{y}O_{1-x-y}), Al—Ge oxide (AlₓGe_{y}O_{1-x-y}), W—Ge oxide (WₓGe_{y}O_{1-x-y}), Cu—Ge oxide (CuₓGe_{y}O_{1-x-y}), Ni—Ge oxide (NiₓGe_{y}O_{1-x-y}), W—Ti oxide (WₓTi_{y}O_{1-x-y}), Al—Ti oxide (AlₓTi_{y}O_{1-x-y}) and arbitrary combinations thereof; and
forming a second electrode on the resistance switching layer.

8. The method according to claim 7, wherein the step of the forming of the resistance switching layer comprises:
forming a first transition metal oxides (TMO) layer and a material layer on the first electrode layer, wherein the material layer is made of a material other than that of the first TMO layer;
performing a thermal annealing treatment to the first TMO layer and the material layer to form a metal alloy layer; and
oxidizing the metal alloy layer.

9. The method according to claim 8, wherein the first TMO layer is formed prior to or latter than the forming of the material layer.

10. The method according to claim 8, wherein the first TMO layer comprises titanium (Ti), the material layer comprises silicon (Si), and the first TMO layer has a thickness greater than that of the material layer.

11. The method according to claim 8, wherein the material layer is a second TMO layer comprising a metal selected from a group consisting of hafnium (Hf), tungsten (W), aluminum (Al), copper (Cu), nickel (Ni), germanium (Ge), Ti, zirconium (Zr), niobium (Nb), tantalum (Ta) and the arbitrary combinations thereof.

12. The method according to claim 8, wherein the first TMO layer has a thickness substantially ranging from 1 Å to 50 Å; and the material layer has a thickness substantially ranging from 1 Å to 50 Å.

13. The method according to claim 8, wherein the thermal annealing treatment is performed in a temperature ranging from 50° C. to 850° C. for a time longer than 40 seconds.

14. The method according to claim 8, wherein the metal alloy layer is oxidized using oxygen-containing plasma to bombard the metal alloy layer.

15. The method according to claim 8, wherein the metal alloy layer is oxidized by a thermal oxidation directly performed in an oxidation furnace.

16. The method according to claim 7, wherein the resistance switching layer has a thickness substantially ranging from 1 Å to 200 Å.

17. (canceled)

18. The method according to claim 7, further comprising a step of forming metal oxide layer between the first electrode and the second electrode.

19. The method according to claim 18, wherein the metal oxide layer is made of at least one of TiOx and TiON.

20. The method according to claim 7, wherein the resistive memory device has 10 to 1024 states within a resistance interval ranging of 10 K-Ohm to 200 K-Ohm, when a plurality of set/reset pulses are applied thereto.
